(19) United States
(12) Patent Application Publication
(10) Pub. No.: US 2005/0130449 A1
(43) Pub. Date: Jun. 16, 2005

(54) Method of forming an oxide layer using a mixture of a supercritical state fluid and an oxidizing agent

(76) Inventors: Ping Chuang, Tao-yuan (TW); Yu-Liang Lin, Hsin-Chu (TW); Mei-Sheng Zhou, Singapore (SG)

Correspondence Address: SLATER & MATSIL, L.L.P., 17950 PRESTON ROAD, SUITE 1000, DALLAS, TX, 75252, US

(21) Appl. No.: 10/797,318

(22) Filed: Mar. 10, 2004

Related U.S. Application Data
(60) Provisional application No. 60/529,525, filed on Dec. 15, 2003.

(51) Int. Cl. H01L 21/31; H01L 21/469

(52) U.S. Cl. 438/787

(57) ABSTRACT

A method of forming an oxide layer. A fluid, such as water, is heated and pressurized to supercritical or near-supercritical conditions and mixed with at least one oxidizing agent. The supercritical state mixture of the fluid and at least one oxidizing agent is then applied on the workpiece, forming an oxide layer on the workpiece. The at least one oxidizing agent may comprise nitrogen, and the oxide layer formed on the workpiece may comprise a nitrogen doped oxide.

This application claims the benefit of U.S. Provisional Application No. 60/529,525, filed on Dec. 15, 2003, entitled “Method of Forming an Oxide Layer Using a Mixture of a Supercritical State Fluid and an Oxidizing Agent,” which application is hereby incorporated herein by reference.

### TECHNICAL FIELD

The present invention relates generally to the fabrication of semiconductor devices, and more particularly to a method of fabricating an oxide layer on a semiconductor device.

### BACKGROUND

Semiconductor devices are typically fabricated by sequentially depositing insulating (or dielectric) layers, conductive layers and semiconductive layers of material over a semiconductor substrate, and patterning the various layers using lithography to form circuit components and elements thereon. One type of insulating layer commonly deposited on semiconductor devices is an oxide layer. Wet oxidation is widely used in the semiconductor industry for forming a high quality oxide film. Wet oxidation may be represented by Eq. 1:
Si+H₂O→SiO₂+H₂ and Si+O₂→SiO₂. Eq. 1
However, wet oxidation is often undesirable for use in some applications because the oxidation rate is very slow, e.g., about 1-2 Å/min, which causes a decreased throughput of semiconductor devices in the fabrication process and increases costs. The deposition rate of wet oxidation is dependent on several parameters, such as reaction temperature, crystal orientation of the substrate, and ambient humidity, as examples.

Supercritical fluids or solutions are created when the temperature and pressure of a solution are above the critical temperature and pressure of the fluid. In a supercritical fluid, there is no differentiation between the liquid and gas phases, and the fluid comprises a dense gas in which the saturated vapor and saturated liquid states are identical. Near-supercritical fluids or solutions exist when the reduced temperature and pressure of a solution are both greater than about 0.8×(T_{c}, P_{c}), but the solution is not yet in the supercritical phase. Due to their high density, supercritical and near-supercritical fluids possess superior solvating properties.

Supercritical fluids have been used in thin film processing and other applications as developer reagents or extraction solvents. Murthy et al. (U.S. Pat. No. 4,737,384) describe a physical deposition method for depositing metals and polymers onto substrates by dissolving the metal or polymer in a solvent at supercritical temperature, and reducing the temperature and pressure to deposit the metals and polymer onto a substrate. Sievers et al. (U.S. Pat. No. 4,970,093) teach a chemical vapor deposition method (CVD) in which a supercritical fluid is used to dissolve a precursor, the solution is rapidly expanded, and a chemical reaction is induced in the supercritical solution near a substrate surface to deposit a film by CVD. Watkins et al. (U.S. Pat. No. 5,789,027) describe a method termed Chemical Fluid Deposition (CFD) for depositing a material onto a substrate surface, in which a supercritical fluid is used to dissolve a precursor of the material to be deposited, a substrate is exposed to the solution, and a reaction reagent is introduced that initiates a chemical reaction involving the precursor, thereby depositing the material onto the substrate.

Although the prior art methods described above take advantage of the unique properties of supercritical fluids, the utility of supercritical fluids in semiconductor fabrication has only begun to be realized.

### SUMMARY OF THE INVENTION

Embodiments of the present invention achieve technical advantages by using a supercritical fluid to form a layer of oxide on a surface of a semiconductor device. An oxidizing agent is mixed with a fluid such as water in a supercritical or near-supercritical state, and a substrate or workpiece is exposed to the mixture to form an oxide layer on exposed surfaces of the workpiece. In one embodiment, the method includes introducing nitrogen into the oxide film.

In accordance with a preferred embodiment of the present invention, a method of forming an oxide layer includes providing a workpiece and providing a fluid, the fluid having a temperature and a pressure. The temperature and pressure of the fluid are increased until the fluid reaches a supercritical or near-supercritical state. At least one oxidizing agent is provided, and the supercritical or near-supercritical state fluid is combined with the at least one oxidizing agent to form a supercritical or near-supercritical state mixture. The supercritical or near-supercritical state mixture is applied on the workpiece to form an oxide layer on the workpiece.

In accordance with another preferred embodiment of the present invention, a method of forming an oxide layer includes providing a workpiece, and exposing the workpiece to a mixture of a supercritical state fluid or near-supercritical state fluid and at least one oxidizing agent, forming a layer of oxide on the workpiece.

In accordance with yet another preferred embodiment of the present invention, a method of forming an oxide layer includes providing a workpiece, the workpiece having a surface, combining water in a supercritical state with an oxidizing agent, and exposing the workpiece to the combined supercritical water and oxidizing agent, forming an oxide layer on the surface of the workpiece.

Advantages of preferred embodiments of the present invention include removing surface contaminations and forming an oxide film simultaneously. Nitrogen can be introduced to dope nitrogen into the oxide film formed, in one embodiment. Oxide films may be formed at a faster rate than prior art oxide formation methods. Embodiments of the invention result in semiconductor devices having high quality and density oxide layers, and increased throughput.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of embodiments of the present invention and the advantages thereof, reference is now made to the following descriptions taken in conjunction with the accompanying drawings, in which:

FIG. 1 illustrates the state transition of a material such as water into solid, liquid, gas and supercritical phases;

FIG. 2 is a partial cross-sectional view schematically illustrating a thin film forming apparatus for forming an oxide thin film in a supercritical fluid according to embodiments of the present invention;

FIGS. 3A and 3B illustrate cross-sectional views of a field effect transistor formed using an embodiment of the present invention at various stages of manufacturing; and

FIG. 4 illustrates a cross-sectional view of a stacked metal-insulator-metal (MIM) capacitor formed using an embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely in semiconductor device fabrication. The invention may also be applied, however, to other applications where the formation of an oxide layer is required.

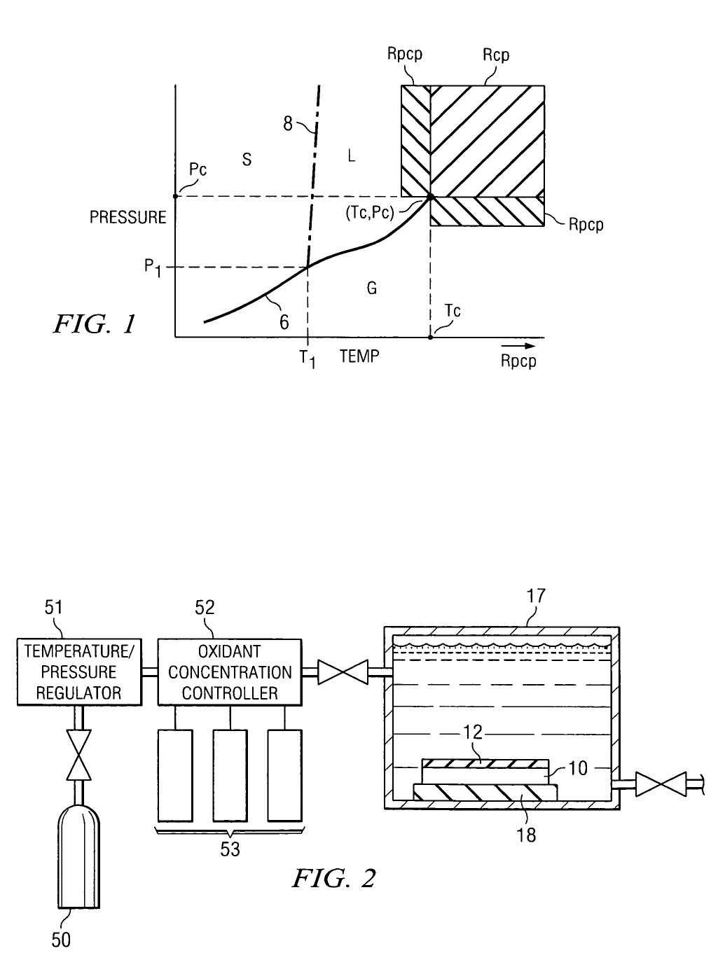

With reference now to FIG. 1, there is shown the state transition of a material such as water and other materials, represented by a curve 6/8. The axis of abscissas represents the temperature, while the axis of ordinates represents the pressure. The region S left of region 8 and above region 6 of the curve 6/8 represents pressures and temperatures at which the material is a solid. The region L right of region 8 and above region 6 of the curve 6/8 represents pressures and temperatures at which the material is a liquid. Temperature T₁ and pressure P₁ represent a point at which the material transitions from a solid to a liquid or gas, for example. The region G below region 6 of the curve 6/8 represents pressures and temperatures at which the material is a gas. The material is a fluid in the gas or liquid phase.

The coordinates (T_{c}, P_{c}) define a critical point where the temperature and pressure are equal to the critical temperature T_{c} and critical pressure P_{c}, respectively. A region where the temperature and pressure are equal to or higher than the critical temperature T_{c} and critical pressure P_{c}, respectively, is defined as a supercritical region R_{cp}. In the supercritical region R_{cp}, the fluid is defined to be in a supercritical state. A region where the temperature is equal to or higher than the critical temperature T_{c} but the pressure is slightly lower than the critical pressure P_{c}, and a region where the pressure is equal to or higher than the critical pressure P_{c} but the temperature is slightly lower than the critical temperature T_{c}, are defined as near-supercritical regions R_{pcp}. When the material is in the supercritical region R_{cp}, the material exhibits different properties than when the material is in the gas, liquid or solid phases.

Next, a technique of forming an oxide layer in a supercritical or near-supercritical fluid combined with an oxidizing agent will be described in accordance with an embodiment of the present invention. FIG. 2 shows a partial cross-sectional view schematically illustrating a thin film forming apparatus for forming an oxide layer or thin film using an oxidizing agent combined with a supercritical or near-supercritical fluid according to the present invention. As shown in FIG. 2, the thin film forming apparatus may include a vessel 17 for forming an oxide layer 12 on a workpiece 10 by a wet oxidization process, and a sample stage 18 with a heater for supporting the workpiece thereon while heating it. The workpiece 10 is placed on the sample stage 18 during the oxide film forming process. A feeding system for supplying the supercritical water and oxidizing agents into the vessel 17 may includes a cylinder 50, a temperature/pressure regulator 51, an oxidant concentration controller 52, and an oxidant feeder 53, for example, as shown.

In accordance with embodiments of the present invention, a fluid in a supercritical or near-supercritical state is supplied from the cylinder 50. The fluid may comprise water or CO₂, as examples, although other fluids may alternatively be used. The temperature/pressure regulator 51 is adapted to control the temperature and pressure of the fluid to be supplied in such a manner as to make the fluid enter the supercritical or near-supercritical state. The oxidant concentration controller 52 is adapted to control the concentration of the one or more oxidants, which are supplied from the oxidant feeder 53 as oxidizing agents for the oxide layer 12 that will be formed on the workpiece 10. The temperature/pressure regulator 51 may be connected to the cylinder 50 via a pipe. The controller 51 is adapted to control the temperature and pressure of the supercritical fluid.

The fluid in a preferred embodiment comprises H₂O that is held in the supercritical state or region R_{cp} of FIG. 1, for example. In this embodiment, the liquid or gaseous H₂O is supplied from the cylinder 50 at equal to or higher than the critical temperature of H₂O (374° C.) and equal to or higher than the critical pressure of H₂O (221 bar), respectively, thereby producing a supercritical or near-supercritical fluid to be supplied to the vessel 17. Above its critical point, water behaves as a nonpolar rather than polar solvent, due primarily to the loss of hydrogen bonding that occurs under these conditions, which is indicated by a decrease in the dielectric constant of H₂O from 80 at ambient conditions to less than 5 when H₂O is in a supercritical state. Thus, nonpolar organic materials are substantially completely soluble in supercritical water along with O₂, and can be rapidly and efficiently oxidized to CO₂ and H₂O, for example.

In another embodiment, the fluid comprises H₂O that is held in near-supercritical regions R_{pcp} (of FIG. 1). In this embodiment, the H₂O is supplied from the cylinder at a temperature of about 299° C. to about 374° C., and at a pressure of about 176 bar to about 221 bar.

The fluid that is combined with an oxidizing agent in accordance with embodiments of the present invention to form an oxide layer may alternatively comprise CO₂ or other fluids, for example. Preferably, in one embodiment, the temperature of heating the fluid to supercritical near-supercritical conditions is about 300° C. to about 750° C., and the pressure of pressurizing the fluid to supercritical or near-supercritical conditions is about 176 to about 440 bar, as examples, although alternatively, other temperatures and pressures may be used.

The oxidant feeder 53 includes at least one container. Each container is adapted to store oxidizing agents for the oxide layer 12 to be formed on the workpiece 10. In accordance with an embodiment of the invention, the oxide layer 12 is formed by exposing the workpiece 10 to an oxidant (also referred to herein as an oxidizing agent) combined with a supercritical fluid or near-supercritical fluid. The oxidizing agent in accordance with one embodiment of the present invention comprises O₁, O₃, or H₂O₂, which have a strong oxidation capability. In another embodiment, the oxidizing agent comprises a nitrogen-containing substance, such as N₂O, NO₂, N₂O₂, or NO as examples. The oxidizing agent may alternatively comprise other oxidants, and may comprise combinations of O₂, O₃, H₂O₂, N₂O, NO₂, N₂O₂, NO, and other oxidants, for example.

In another embodiment, the oxidizing agent may include other oxidants that have strong oxidation capability at high temperature and pressure, such as organic alcohol (e.g., CHOH, C₂H₅OH), organic acid (e.g., HCOOH, CH₃COOH), or organic aldehyde (e.g., HCHO, CH₃CHO), as examples. If these chemistries are added to the supercritical or near-supercritical fluid, then an even higher quality oxide layer 12 may be formed on a workpiece 10, depending on the temperature or pressure.

The oxidant concentration controller 52 is connected to the temperature/pressure regulator 51 and the oxidant feeder 53 via respective pipes. The oxidant concentration controller 52 is adapted to mix the oxidizing agents as respective solutes, for example, in supercritical water. The oxidant concentration controller 52 is also adapted to control the concentration of the solutes at predetermined concentrations and supply the mixture to the vessel 17.

In accordance with an embodiment of the invention, the formation of the oxide layer 12 and removal of any contaminants from the workpiece surface are carried out simultaneously. This may be achieved in the following manner. First, the oxidant concentration controller 52 adjusts the mixture ratio of supercritical water that has been supplied from the temperature/pressure regulator 51 and the oxidants that have been supplied from the oxidant feeder 53. In one illustrative embodiment, the concentrations of the oxidizing agent in supercritical water are all controlled at about 10% by volume. The flow rate of the supercritical state mixture of the water and oxidizing agents on the workpiece may comprise about 0.1 liter per minute to about 25 liters per minute, for example.

In the vessel 17, the temperature of the workpiece may be controlled by the sample stage 18, e.g., at about 650° C., and the mixture of supercritical water and oxidant that has been supplied from the oxidant concentration controller 52 is applied on the surface of the workpiece 10, thereby forming an oxide layer 12. Again, preferably in one embodiment, surface contaminations are removed simultaneously with the formation of the oxide layer 12. The removal of surface contaminations may be accomplished by organic compound oxidation and decomposition, for example.

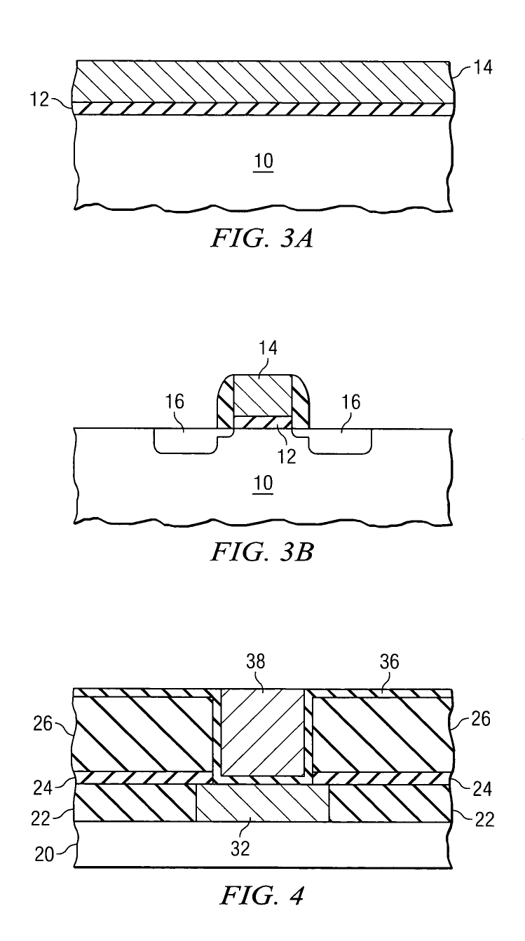

FIGS. 3A and 3B illustrate a field effect transistor formed utilizing processing steps that include the method of the present invention. Specifically, FIG. 3A illustrates a structure formed after an oxide layer 12 is formed on an upper surface of a semiconductor workpiece 10. The workpiece 10 shown in FIG. 3A preferably is comprised of conventional materials well known in the art. For example, the workpiece 10 may be comprised of a semiconductor material including, but not limited to: Si, Ge, SiGe, GaAs, InAs, InP and other III/V or IIVI semiconductor compounds. The workpiece 10 may also include a layered substrate comprising the same or different semiconductor materials, e.g., Si/Si or Si/SiGe, as well as a silicon-on-insulator (SOI) substrate. The workpiece may be n- or p-type depending on the device to be fabricated, for example. The workpiece 204 may include other conductive layers or other semiconductor elements, such as transistors or diodes, as examples. Additionally, the workpiece 10 may contain active device regions, wiring regions, isolation regions or other regions that are typically present in CMOS-containing devices. For clarity, these regions are not shown in the drawings, but may nevertheless be formed within or on the workpiece 10.

The workpiece 10 is then placed within a reaction vessel 17 such as the one shown in FIG. 2. The workpiece 10 is exposed to a supercritical state mixture of water and at least one oxidizing agent, thereby forming an oxide layer 12, and in one embodiment, removing surface contaminations simultaneously with the formation of the oxide layer 12. The oxide layer 12 in this embodiment comprises a gate oxide.

The oxide layer 12 may be comprised of an oxide, oxynitride or any combination thereof including multilayers. In one preferred embodiment, the oxide layer 12 comprises an oxynitride. A nitrogen-doped gate oxide may be particularly advantageous in certain applications, for example. When an oxynitride is employed as the oxide layer 12, the oxide layer 12 may be formed in the presence of any oxygen/nitrogen-containing oxidant, which may be mixed with supercritical water, for example. Suitable oxygen/nitrogen-containing oxidants include, but are not limited to: NO, NO₂, N₂O₂, N₂O and combinations thereof, for example. In one preferred embodiment, the oxide layer 12 is formed in an oxygen/nitrogen-containing ambient that comprises from about 10% to 50% NO which is admixed in supercritical water. The flow rate of the supercritical state mixture of the water and oxidizing agents on the workpiece may comprise about 0.1 liter per minute to about 25 liters per minute, for example.

The thickness of the oxide layer 12 formed utilizing embodiments of the present may comprise a thickness of from about 100 to about 400 nm, for example, although alternatively, the oxide layer 12 thickness may comprise other thicknesses. Preferably the oxide layer 12 is formed faster than prior art wet deposition techniques. For example, the oxide layer 12 is formed at a rate of about 5 Angstroms per minute or greater in a preferred embodiment.

A subsequent material 14, which may comprise a gate material or gate conductor, as examples, may then be formed on the oxide layer 12, as shown in FIG. 3A. The material 14 may comprise a conductive material, a material that can be made conductive via a subsequent process such as ion implantation, or any combination thereof. Illustrative examples of suitable gate materials include, but are not limited to: polysilicon, amorphous silicon, elemental metals that are conductive such as W, Pt, Pd, Ru, Rh, Re, and Ir, alloys of these elemental metals, silicide or nitrides of these elemental metals and combinations thereof, e.g., a gate stack including a layer of polysilicon and/or a layer of conductive metal, as examples.

After forming material 14 on the oxide layer 12, the workpiece 10 may then be patterned utilizing conventional processing steps well known in the art which are capable of forming the patterned structure shown in FIG. 3B. Specifically, the structure shown in FIG. 3B may be formed by lithography, material deposition and etching. The lithography process may include applying a photoresist (not shown) to the top surface of material 14 (a gate contact in one embodiment), exposing the photoresist to a pattern of radiation, and developing the pattern utilizing a conventional resist developer solution. Etching is typically performed utilizing a conventional dry etching process such as reactive-ion etching, plasma etching, ion beam etching, or a combination thereof, as examples. The etching step may remove portions of the gate contact 14 and the underlying gate oxide layer 12 that are not protected by the patterned photoresist. Following the etching process, the patterned photoresist is removed utilizing a conventional stripping process well known in the art, leaving the structure shown, for example, in FIG. 3B. At this point of the present invention, the patterned gate contact region 14 may be subjected to a conventional ion implantation step and an activation annealing process to form source/drain extension regions 16. Other implantation or doping processes may be used to form the source and drain regions 16, for example. A field effect transistor (FET) comprising gate contact 14, gate oxide 12, and source/drain regions 16 is thus formed in accordance with one embodiment of the invention.

In another embodiment of the present invention, as shown in FIG. 4, a metal-insulator-metal (MIM) capacitor is formed on a semiconductor surface using the novel methods of forming an oxide layer described herein. A first layer of dielectric 22 is deposited over a workpiece or semiconductor surface 20. A first opening is created in the first layer of dielectric 22 and filled with a planarized first layer of metal, forming a metal plug 32 in the first layer of dielectric 22 to serve as a first electrode 32 of the capacitor. An etch stop layer 24 followed by a second layer of dielectric 26 are deposited over the surface of the first layer of dielectric 22, including the surface of the first electrode 32 of the capacitor. The etch stop layer 24 and the second layer of dielectric 26 are etched, creating a second opening in the layers of etch stop 24 and second layer of dielectric 26 that aligns with the first electrode 32 of the capacitor.

The workpiece 20 is exposed to a mixture of a supercritical state fluid such as water and an oxidizing agent such as O₂, O₃, H₂O₂, N₂O, NO₂, N₂O₂, NO, CHOH, C₂H₅OH, HCOOH, CH₃COOH, HCHO, CH₃CHO, other oxidants, or combinations thereof, as examples, as described above, to form capacitor dielectric 36, for example. The capacitor dielectric 36 may be comprised of an oxide, oxynitride or any combination thereof, including multilayers thereof. The thickness of the capacitor dielectric 36 may comprise about 100 to about 400 nm, and may alternatively comprise other thicknesses, for example.

A second layer of metal 38 is then deposited over the layer of capacitor dielectric 36. The second layer of metal 38 is polished down to the surface of the layer of capacitive dielectric 36. The surface of the polished second layer of metal 38 is in a plane with the surface of the layer of capacitor dielectric 36 where the layer of capacitor dielectric 36 overlays the second layer of dielectric 26, for example. The MIM capacitor includes a top plate 38, capacitor dielectric 36 formed utilizing embodiments of the present invention, and a bottom plate 32, as shown.

The method of forming an oxide layer described herein is particularly advantageous when used to oxidize high dielectric constant (K) materials disposed over the surface of a workpiece, such as Hf/Zr, Si/Al, Ti/Sr, Y/Ba, or La/Ta, as examples.

When the fluid combined with the oxidizing agent described herein comprises supercritical water, this is advantageous for several reasons. Because supercritical water has a high O₂ solubility, the oxidation rate is increased. The high humidity of supercritical water also contributes to an increased oxidation rate, as shown by Eq. 2 and Eq. 3:
Si+H₂O→SiO₂+H₂ Eq. 2
Si+O₂→SiO₂ Eq. 3

Furthermore, the low polarity of supercritical water results in increased organic solubility, as shown in Eq. 4:
CₓH_{y(s)}→CₓH_{y(g)}+O₂→CO₂+H₂O Eq. 4

In addition, because supercritical water has a low surface tension, high aspect ratio features are filled completely rather than having void formation in lower regions of the high aspect ratio structures. Because the supercritical water oxidizes and cleans the workpiece surface simultaneously, reduced cost and improved performance are achieved.

Advantages of embodiments of the invention include providing a novel method of forming an oxide layer that decreases the oxide formation time and provides a high quality oxide layer. Nitrogen can be introduced during the oxide formation, forming an oxynitride layer on the workpiece. Increased throughput of semiconductor device fabrication can be achieved in accordance with embodiments of the present invention. The surface of a workpiece is advantageously cleaned of contaminants simultaneously with the formation of the oxide layer, in accordance with embodiments of the invention.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. While embodiments of the present invention are described herein in the formation of a gate oxide layer of a FET (FIGS. 3A and 3B) and a MIM capacitor (FIG. 4), the methods of forming an oxide layer described herein are also useful and have application in other semiconductor device applications, for example.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method of forming an oxide layer, the method comprising:
providing a workpiece;
providing a fluid, the fluid having a temperature and a pressure;
increasing the temperature and the pressure of the fluid until the fluid reaches a supercritical or near-supercritical state;
providing at least one oxidizing agent;
combining the supercritical or near-supercritical state fluid with the at least one oxidizing agent to form a supercritical or near-supercritical state mixture; and
applying the supercritical or near-supercritical state mixture on the workpiece to form an oxide layer on the workpiece.

2. The method according to claim 1, wherein the workpiece includes surface contaminations on a surface thereof, wherein the surface contaminations are removed simultaneously with the forming of the oxide layer.

3. The method according to claim 1, wherein the fluid comprises H₂O or CO₂.

4. The method according to claim 1, wherein increasing the temperature of the fluid comprises increasing the temperature of the fluid to a temperature of about 300° C. to about 750° C.

5. The method according to claim 1, wherein increasing the pressure of the fluid comprises increasing the pressure to a pressure of about 176 bar to about 440 bar.

6. The method according to claim 1, wherein applying the supercritical or near-supercritical state mixture on the workpiece comprises a flow rate of about 0.1 liter per minute to about 25 liters per minute.

7. The method according to claim 1, wherein providing the at least one oxidizing agent comprises providing O₂, O₃, H₂O₂, NO, N₂O, NO₂, N₂O₂, organic alcohol, organic acid, organic aldehyde or combinations thereof.

8. The method according to claim 1, wherein providing the at least one oxidizing agent comprises providing NO, N₂O, NO₂, N₂O₂, or combinations thereof.

9. The method according to claim 8, wherein forming the oxide layer comprises forming nitrogen doped oxide.

10. The method according to claim 1, wherein the workpiece comprises a semiconductor material selected from the group consisting of Si, Ge, SiGe, GaAs, InAs, InP, Si/Si, Si/SiGe, and silicon-on-insulators.

11. The method according to claim 1, wherein the workpiece includes a material layer formed thereon, wherein forming the oxide layer comprises forming the oxide layer over the material layer.

12. The method according to claim 11, wherein forming the oxide layer comprises forming a capacitor dielectric layer over the material layer.

13. The method according to claim 12, wherein the material layer comprises a bottom capacitor plate of a metal-insulator-metal (MIM) capacitor, further comprising forming a top capacitor plate over the capacitor dielectric layer.

14. The method according to claim 1, wherein forming the oxide layer comprises forming a gate oxide layer.

15. The method according to claim 14, further comprising:
depositing a gate contact layer over the gate oxide layer;
patterning the gate contact layer and gate oxide layer; and
doping portions of the workpiece to form source and drain regions in the workpiece, forming a transistor device comprising the source and drain regions, gate oxide layer and gate contact layer.

16. The method according to claim 1, wherein forming the oxide layer comprises forming the oxide layer at a rate of about 5 Angstroms per minute or greater.

17. The method according to claim 1, wherein forming the oxide layer comprises forming about 400 to about 800 nm of material.

18. A method of forming an oxide layer, the method comprising the steps of:
providing a workpiece; and
exposing the workpiece to a mixture of a supercritical state fluid or near-supercritical state fluid and at least one oxidizing agent, forming a layer of oxide on the workpiece.

19. The method according to claim 18, wherein the supercritical state fluid or near-supercritical state fluid comprises H₂O or CO₂.

20. The method according to claim 18, wherein the at least one oxidizing agent comprises O₂, O₃, H₂O₂, NO, N₂O, NO₂, N₂O₂, organic alcohol, organic acid, organic aldehyde or combinations thereof.

21. The method according to claim 18, wherein the temperature of the supercritical state fluid or near-supercritical state fluid is about 300° C. to about 750° C., and wherein the pressure of the supercritical state fluid or near-supercritical state fluid is about 176 bar to about 440 bar.

22. The method according to claim 18, wherein exposing the workpiece to the mixture comprises applying the mixture on the workpiece at a flow rate of about 0.1 liter per minute to about 25 liters per minute.

23. The method according to claim 18, wherein the oxidizing agent comprises N₂O, NO₂, N₂O₂, or combinations thereof, and wherein the layer of oxide comprises nitrogen doped oxide.

24. The method according to claim 18, wherein the workpiece includes surface contaminations on a surface thereof, wherein the surface contaminations are removed simultaneously with the forming of the oxide layer.

25. The method according to claim 18, wherein the workpiece includes a material layer formed thereon, wherein forming the layer of oxide comprises forming the layer of oxide on the material layer.

26. The method according to claim 25, wherein forming the layer of oxide comprises forming a capacitor dielectric layer on the material layer.

27. The method according to claim 26, wherein the material layer comprises a bottom capacitor plate of a metal-insulator-metal (MIM) capacitor, further comprising forming a top capacitor plate over the capacitor dielectric layer.

28. The method according to claim 18, wherein forming the layer of oxide comprises forming a gate oxide layer.

29. The method according to claim 28, further comprising:
depositing a gate contact layer over the gate oxide layer;
patterning the gate contact layer and gate oxide layer; and
doping portions of the workpiece to form source and drain regions in the workpiece, forming a transistor device comprising the source and drain regions, gate oxide layer, and gate contact layer.

30. The method according to claim 18, wherein forming the layer of oxide comprises forming the layer of oxide at a rate of about 5 Angstroms per minute or greater.

31. The method according to claim 18, wherein forming the layer of oxide comprises forming about 400 to about 800 nm of material.

32. A method of forming an oxide layer, the method comprising:
providing a workpiece, the workpiece having a surface;
combining water in a supercritical state with an oxidizing agent; and
exposing the workpiece to the combined supercritical water and oxidizing agent, forming an oxide layer on the surface of the workpiece.

33. The method according to claim 32, wherein the oxidizing agent comprises O₂, O₃, H₂O₂, NO, N₂O, NO₂, N₂O₂, organic alcohol, organic acid, organic aldehyde or combinations thereof.

34. The method according to claim 32, wherein the workpiece comprises Si, Ge, SiGe, GaAs, InAs, InP, Si/Si, Si/SiGe, or a silicon-on-insulator substrate.

35. The method according to claim 32, wherein the workpiece surface includes a material layer formed thereon, wherein forming the oxide layer comprises forming the oxide layer on the material layer.
